(19) United States
(12) Patent Application Publication
(10) Pub. No.: US 2013/0148404 A1
(43) Pub. Date: Jun. 13, 2013

(54) ANTIFUSE-BASED MEMORY CELLS HAVING MULTIPLE MEMORY STATES AND METHODS OF FORMING THE SAME

(71) Applicants: Abhijit Bandyopadhyay, San Jose, CA (US); Roy E. Scheuerlein, Cupertino, CA (US); Peter Rabkin, Cupertino, CA (US)

(72) Inventors: Abhijit Bandyopadhyay, San Jose, CA (US); Roy E. Scheuerlein, Cupertino, CA (US); Peter Rabkin, Cupertino, CA (US)

(21) Appl. No.: 13/314,580

(22) Filed: Dec. 8, 2011

(51) Int. Cl. G11C 17/00; H01L 29/92

(52) U.S. Cl. 365/103; 257/532; 257/E29.342

(57) ABSTRACT

In some aspects, a memory cell is provided that includes a steering element and a metal-insulator-metal (“MIM”) stack coupled in series with the steering element. The MIM stack includes a first dielectric material layer and a second dielectric material layer disposed on the first dielectric material layer, without a metal or other conductive layer disposed between the first dielectric material layer and the second dielectric material layer. Numerous other aspects are provided.

### BACKGROUND

This invention relates to non-volatile memories, and more particularly to antifuse-based memory cells having multiple memory states and methods of forming the same.

Non-volatile memory cells that include a diode and antifuse in series (“diode-antifuse memory cells”) are known. For example, Johnson et al. U.S. Pat. No. 6,034,882, which is incorporated by reference in its entirety for all purposes, describes a memory cell that includes a diode in series with a dielectric rupture antifuse. In general, previously known diode-antifuse memory cells have two memory states (e.g., the antifuse is either intact or broken down).

It would be advantageous to increase device density by devising a diode-antifuse memory cell that can have more than two data states.

### SUMMARY

In a first aspect of the invention, a memory cell is provided that includes a steering element and a metal-insulator-metal stack coupled in series with the steering element. The metal-insulator-metal stack includes a first dielectric material layer and a second dielectric material layer disposed on the first dielectric material layer, without a metal or other conductive layer disposed between the first dielectric material layer and the second dielectric material layer.

In a second aspect of the invention, a method is provided for programming a memory cell that includes a metal-insulator-metal stack including a first dielectric material layer, a second dielectric material layer disposed on the first dielectric material layer, and a third dielectric material layer disposed on the second dielectric material layer, without a metal or other conductive layer disposed between the dielectric material layers. The memory cell has a first memory state upon fabrication corresponding to a first read current. The method includes applying a first programming pulse to the memory cell, wherein the first programming pulse does not result in breakdown of the dielectric material layers, and programs the memory cell to a second memory state that corresponds to a second read current greater than the first read current.

In a third aspect of the invention, a monolithic three-dimensional memory array is provided that includes a first memory level monolithically formed above a substrate, and a second memory level monolithically formed above the first memory level. The first memory level includes a plurality of memory cells, wherein each memory cell includes a steering element and a metal-insulator-metal stack coupled in series with the steering element. The metal-insulator-metal stack includes a first dielectric material layer and a second dielectric material layer disposed on the first dielectric material layer, without a metal or other conductive layer disposed between the first dielectric material layer and the second dielectric material layer.

Other features and aspects of the present invention will become more fully apparent from the following detailed description, the appended claims and the accompanying drawings.

### BRIEF DESCRIPTION OF THE DRAWINGS

Features of the present invention can be more clearly understood from the following detailed description considered in conjunction with the following drawings, in which the same reference numerals denote the same elements throughout, and in which:

FIG. 1 is a diagram of an example memory cell in accordance with this invention;

FIG. 2A is a simplified perspective view of an example memory cell in accordance with this invention;

FIG. 2B is a simplified perspective view of a portion of a first example memory level formed from a plurality of the memory cells of FIG. 2A;

FIG. 2C is a simplified perspective view of a portion of a first example three-dimensional memory array in accordance with this invention;

FIG. 2D is a simplified perspective view of a portion of a second example three-dimensional memory array in accordance with this invention;

FIG. 3A is a cross-sectional view of an example memory cell in accordance with this invention;

FIGS. 3B-3G are diagrams of examples of multi-layer antifuse structures in accordance with this invention;

FIGS. 4A-4B are energy band diagrams of an example memory cell in accordance with this invention;

FIGS. 4C-4D are energy band diagrams of another example memory cell in accordance with this invention;

FIG. 5A is a diagram of example I-V characteristics of a memory cell in accordance with this invention;

FIG. 5B is a diagram of example memory states, programming conditions and read currents of a memory cell in accordance with this invention; and

FIGS. 6A-6E illustrate cross-sectional views of a portion of a substrate during an example fabrication of a single memory level in accordance with this invention.

### DETAILED DESCRIPTION

A previously known antifuse memory cell includes a dielectric antifuse in series with a diode, such as a vertical polysilicon diode. As formed, a dielectric antifuse is in an initial high-resistance state. Accordingly, if a read voltage is applied across such a memory cell, little or no current flows through the device. If a larger programming voltage is applied across the device, the dielectric antifuse breaks down, and a low-resistance rupture region forms through the dielectric antifuse. As a result, if a read voltage is applied across a programmed memory cell, substantially more current flows through the device. The difference in current between an unprogrammed memory cell having an intact antifuse and a programmed memory cell having a broken down antifuse can correspond to two different data states of the memory cell.

Some researchers have attempted to develop “multi-level” dielectric antifuse memory cells that can store more than two data states. For example, Yeh et al. U.S. Patent Publication No. 2006/0073642 (“Yeh”) describes a memory cell that includes an “ultra-thin” layer of a dielectric film disposed between first and second electrodes. Yeh asserts that the memory cell can store multiple data states by applying low voltages across the dielectric material layer for intervals of time to cause progressive breakdown of the dielectric material layer, by which a programmable resistance is established representing stored data. Yeh provides only one detailed example of “ultra-thin” dielectric films: oxides, such as oxynitride, having a thickness less than 20 Angstroms, and more preferably about 15 Angstroms or less.

Such previously known multi-level dielectric antifuse memory cells have numerous problems that make such devices unsuitable for use in commercial memory devices. In particular, as dielectric material starts to break down, the resistance of the material decreases. As a result, capacitive discharge from stray capacitance near the memory cell can cause undesirable current surges through the dielectric material, making it difficult to control the progressive breakdown process. This phenomenon can occur even if an external current limiter is used to drive the memory cell. Further, for ultra-thin dielectric materials, such as those described in Yeh, electron tunneling may be significant, which makes control of the progressive breakdown process even more difficult.

As a result of such problems, some previously known multi-level antifuse memory cells have difficulty obtaining repeatable data states. For example, in some previously known progressive breakdown antifuse memory cells, one or more data states may exhibit unacceptably wide variation and/or state jump from a lower data state to higher data states.

Memory cells in accordance with this invention may avoid controllability problems associated with previously known multi-level dielectric antifuse memory cells. In particular, memory cells in accordance with this invention include a multi-layer antifuse structure that includes multiple layers of dielectric material stacked on one another without a metal or other conductive layer disposed between adjacent layers of dielectric material. The conductivity of the multi-layer antifuse structure has more than two substantially stable values that can be sensed as more than two substantially distinct data states.

As described in more detail below, an example memory cell in accordance with this invention includes a multi-layer antifuse structure that has three dielectric material layers, and may be used to provide at least four substantially distinct data states. Without wanting to be bound by any particular theory, it is believed that: (1) a first data state corresponds to a first conductivity of the multi-layer antifuse structure upon fabrication, (2) a second data state corresponds to a second conductivity of the multi-layer antifuse structure resulting from charge carriers being trapped in a quantum well formed in the multi-layer antifuse structure, (3) a third data state corresponds to a third conductivity of the multi-layer antifuse structure resulting from progressive breakdown of one or more of the dielectric material layers of the multi-layer antifuse structure, and (4) a fourth data state corresponds to a conductivity of the multi-layer antifuse structure resulting from substantially complete breakdown of the dielectric material layers of the multi-layer antifuse structure.

### Example Inventive Memory Cell

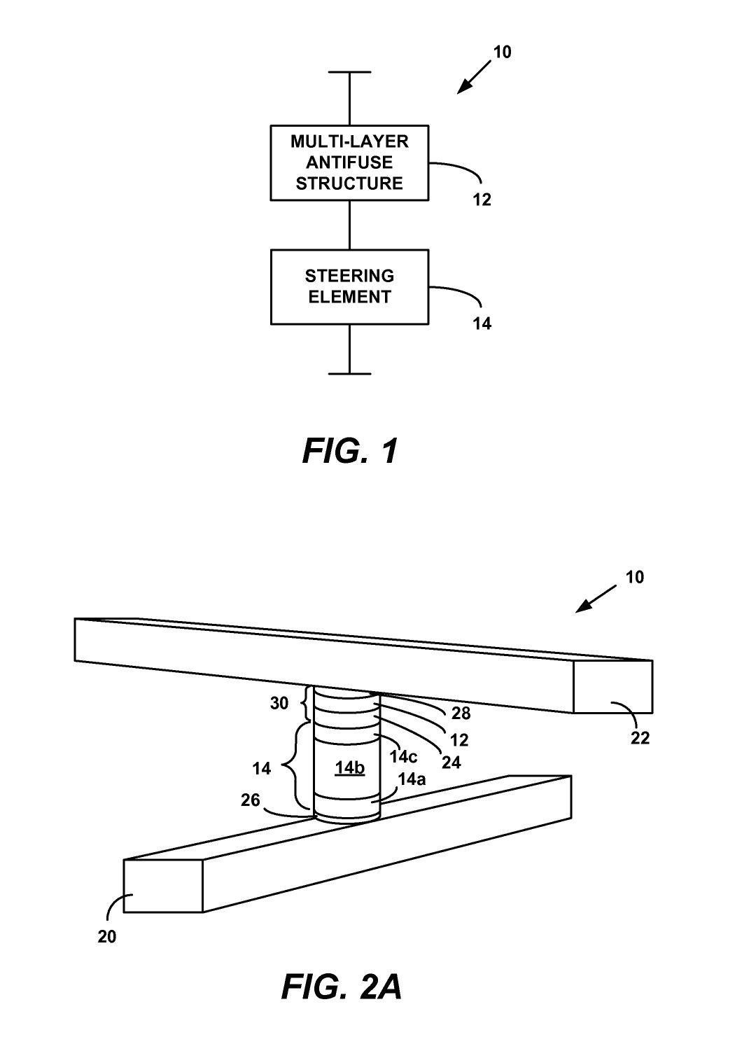

FIG. 1 is a diagram of an example memory cell 10 in accordance with this invention. Memory cell 10 includes a multi-layer antifuse structure 12 coupled to a steering element 14. As described in more detail below, multi-layer antifuse structure 12 includes multiple layers of dielectric material stacked on one another (not separately shown in FIG. 1) without a metal or other conductive layer disposed between adjacent layers of dielectric material. The conductivity of multi-layer antifuse structure 12 has more than two substantially stable values that can be sensed as more than two substantially distinct data states.

Steering element 14 may include a thin film transistor, a diode, a metal-insulator-metal tunneling current device, or another similar steering element that exhibits non-ohmic conduction by selectively limiting the voltage across and/or the current flow through multi-layer antifuse structure 12. In this manner, memory cell 10 may be used as part of a two- or three-dimensional memory array and data may be written to and/or read from memory cell 10 without affecting the state of other memory cells in the array.

As described in more detail below, an example multi-layer antifuse structure 12 includes three dielectric material layers, with the second dielectric material layer sandwiched between the first and third dielectric material layers. In some example embodiments, the first and third dielectric material layers have a wider band-gap than that of the second dielectric material layer to form a quantum well. In addition, in some example embodiments, one of the dielectric material layers has a thickness that is greater than the thickness of the other two dielectric material layers.

Without wanting to be bound by any particular theory, it is believed that multi-layer antifuse structure 12 may be used to provide at least four distinct, controllable data states. In particular, multi-layer antifuse structure 12 may have a first conductivity upon fabrication, in which a first read current flows through memory cell 10 upon application of a read voltage. The first conductivity of multi-layer antifuse structure 12 corresponds to a first data state of memory cell 10.

Upon application of a first programming voltage across memory cell 10, multi-layer antifuse structure 12 switches to a second conductivity, in which a second read current (higher than the first read current) flows through memory cell 10 upon application of the read voltage. The second conductivity of multi-layer antifuse structure 12 corresponds to a second data state of memory cell 10.

Without wanting to be bound by any particular theory, it is believed that in the second data state, charge carriers are trapped in the quantum well, causing an increase in tunneling current through multi-layer antifuse structure 12. In this regard, it is believed that the second conductivity of multi-layer antifuse structure 12 is not the result of progressive breakdown of the dielectric material layers of multi-layer antifuse structure 12.

Upon application of a second programming voltage across memory cell 10, while limiting current through memory cell 10, multi-layer antifuse structure 12 switches to a third conductivity, in which a third read current (higher than the second read current) flows through memory cell 10 upon application of the read voltage. The third conductivity of multi-layer antifuse structure 12 corresponds to a third data state of memory cell 10.

Without wanting to be bound by any particular theory, it is believed that in the third memory state, multi-layer antifuse structure 12 exhibits progressive breakdown (also referred to herein as “soft breakdown”) in which dielectric material begins to break down, without experiencing complete dielectric breakdown. In particular, it is believed that the thicker dielectric material layer experiences soft breakdown, while the other two dielectric material layers remain substantially intact. For example if the second dielectric material layer is thicker than the first and third dielectric material layers, it is believed that the resistance of the first and/or the third dielectric material layers may limit capacitive discharge through the device during a programming event, resulting in greater control of the soft breakdown process. As a result of the soft breakdown, multi-layer antifuse structure conducts an increased leakage current.

Upon application of a third programming voltage across memory cell 10, without limiting current through memory cell 10, multi-layer antifuse structure 12 switches to a fourth conductivity, in which a fourth read current (higher than the third read current) flows through memory cell 10 upon application of the read voltage. The fourth conductivity of multi-layer antifuse structure 12 corresponds to a fourth data state of memory cell 10. Without wanting to be bound by any particular theory, it is believed that in the fourth memory state, multi-layer antifuse structure 12 exhibits substantially complete dielectric breakdown. As a result of the complete breakdown, multi-layer antifuse structure conducts an increased breakdown current.

Persons of ordinary skill in the art will understand that memory cells in accordance with this invention may be programmed by applying programming voltages across the memory cell, or by supplying programming currents to the memory cell.

In addition, persons of ordinary skill in the art will understand that the programming steps described above may include applying programming voltages/currents more than once. For example, to program memory cell 10 to a second data state that has a predetermined range of read current values, a first programming pulse having the first programming voltage may be applied across memory cell 10, and then the read current of memory cell 10 may be measured. If the measured read current is not within the predetermined range, a second programming pulse having the first programming voltage may be applied across memory cell 10, and then the read current of memory cell 10 may be measured. This process may be iteratively repeated until memory cell 10 exhibits a read current within the predetermined range of current values. The same iterative programming process may be used for each data state.

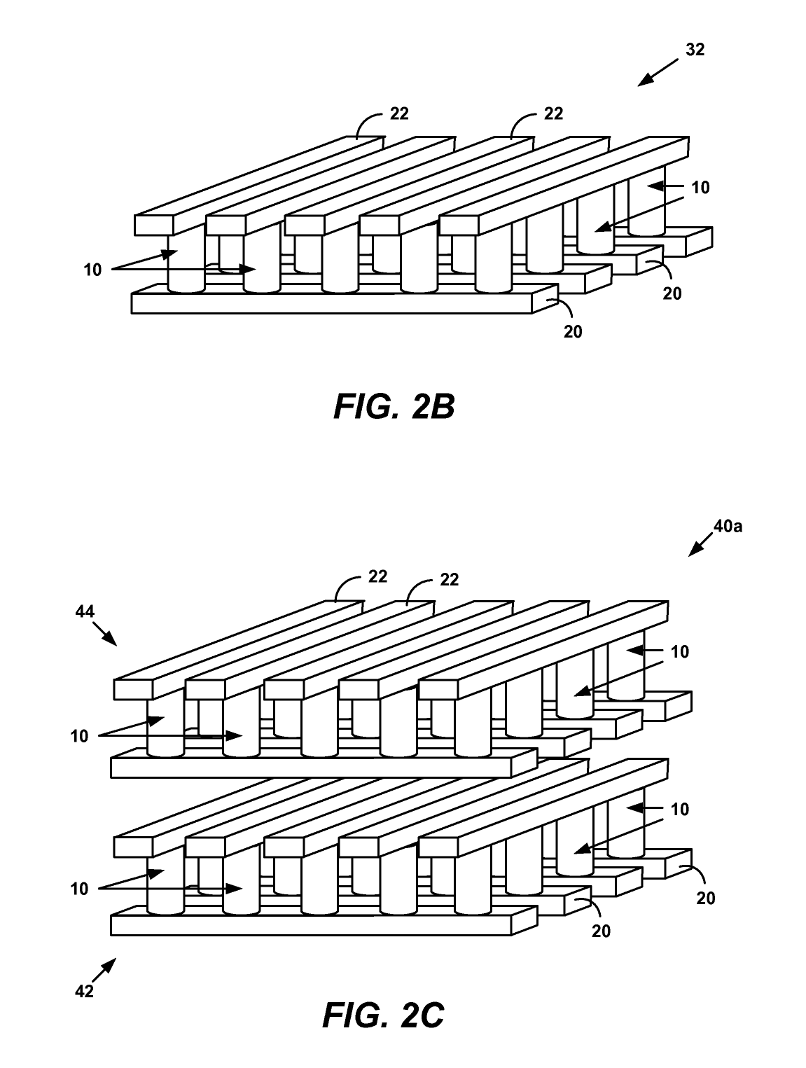

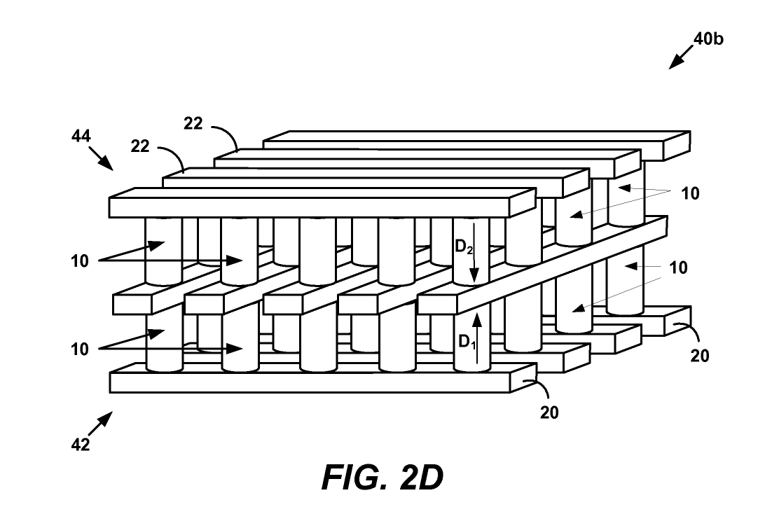

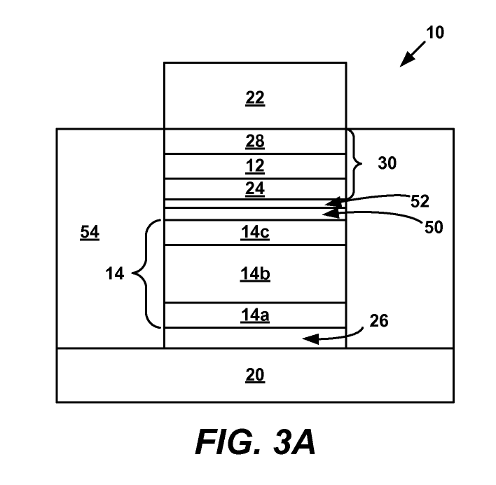

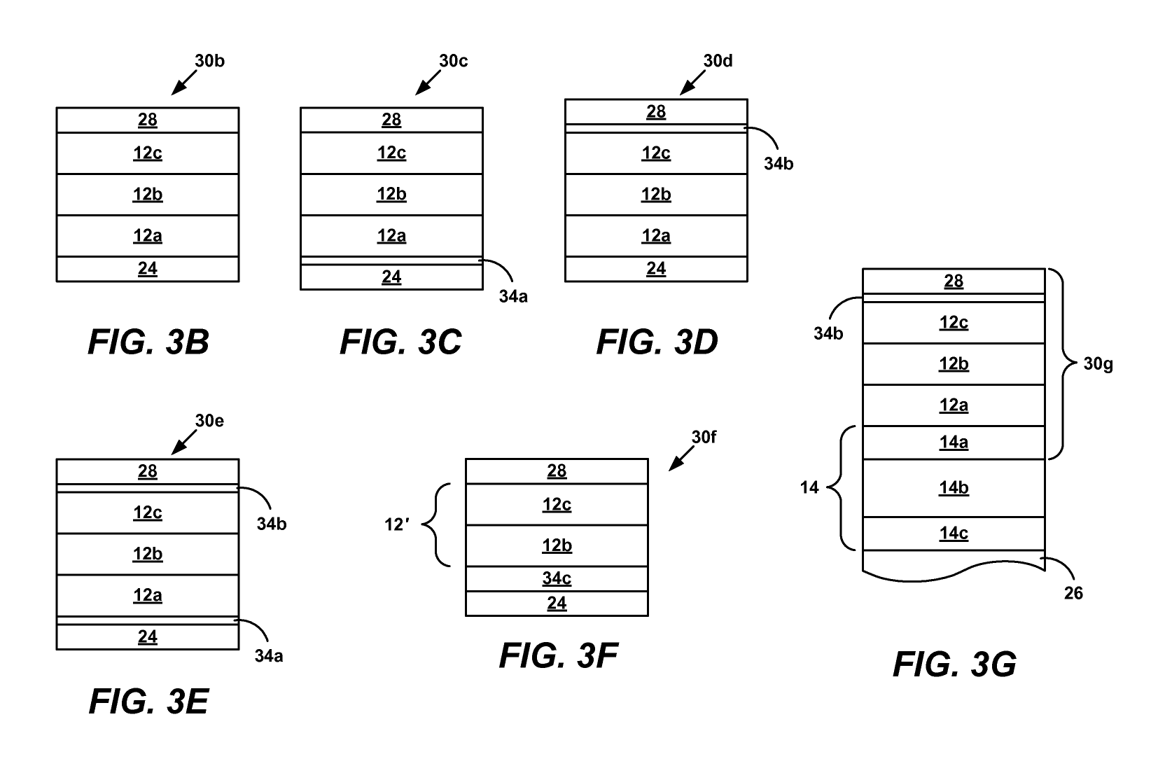

Example embodiments of memory cell 10, multi-layer antifuse structure 12 and steering element 14 are described below with reference to FIGS. 2A-2D and FIGS. 3A-3F.

### Example Embodiments of Memory Cells and Memory Arrays

FIG. 2A is a simplified perspective view of an example memory cell 10 in accordance with this invention that includes a steering element 14 and a multi-layer antifuse structure 12. Multi-layer antifuse structure 12 is coupled in series with steering element 14 between a first conductor 20 and a second conductor 22.

In some embodiments, a first conducting layer 24 may be formed between multi-layer antifuse structure 12 and steering element 14, a barrier layer 26 may be formed between steering element 14 and first conductor 20, and a second conducting layer 28 may be formed between multi-layer antifuse structure 12 and second conductor 22. First conducting layer 24, barrier layer 26, and second conducting layer 28 each may include titanium, titanium nitride (“TiN”), tantalum, tantalum nitride (“TaN”), tungsten, tungsten nitride (“WN”), molybdenum or another similar material.

First conducting layer 24, multi-layer antifuse structure 12 and second conducting layer 28 may form a metal-insulator-metal (“MIM”) stack 30 in series with steering element 14, with first conducting layer 24 forming a bottom electrode, and second conducting layer 28 forming a top electrode of MIM stack 30. For simplicity, first conducting layer 24 and second conducting layer 28 will be referred to in the remaining discussion as “bottom electrode 24” and “top electrode 28,” respectively. In some embodiments, multi-layer antifuse structure 12 and/or MIM stack 30 may be positioned below steering element 14.

As discussed above, steering element 14 may include a thin film transistor, a diode, a metal-insulator-metal tunneling current device, or another similar steering element that exhibits non-ohmic conduction by selectively limiting the voltage across and/or the current flow through multi-layer antifuse structure 12. In the example of FIG. 2A, steering element 14 is a diode. Accordingly, steering element 14 is sometimes referred to herein as “diode 14.”

Diode 14 may include any suitable diode such as a vertical polycrystalline p-n or p-i-n diode, whether upward pointing with an n-region above a p-region of the diode or downward pointing with a p-region above an n-region of the diode. For example, diode 14 may include a heavily doped n+ polysilicon region 14a, a lightly doped or an intrinsic (unintentionally doped) polysilicon region 14b above the n+ polysilicon region 14a, and a heavily doped p+ polysilicon region 14c above intrinsic region 14b. It will be understood that the locations of the n+ and p+ regions may be reversed. Example embodiments of diode 14 are described below with reference to FIG. 3A.

First conductor 20 and/or second conductor 22 may include any suitable conductive material such as tungsten, any appropriate metal, heavily doped semiconductor material, a conductive silicide, a conductive silicide-germanide, a conductive germanide, or the like. In the embodiment of FIG. 2A, first and second conductors 20 and 22, respectively, are rail-shaped and extend in different directions (e.g., substantially perpendicular to one another). Other conductor shapes and/or configurations may be used. In some embodiments, barrier layers, adhesion layers, antireflection coatings and/or the like (not shown) may be used with the first conductor 20 and/or second conductor 22 to improve device performance and/or aid in device fabrication.

FIG. 2B is a simplified perspective view of a portion of a first memory level 32 formed from a plurality of memory cells 10, such as memory cell 10 of FIG. 2A. For simplicity, MIM 30, diode 14, and barrier layer 26 are not separately shown. Memory level 32 is a “cross-point” array including a plurality of bit lines (second conductors 22) and word lines (first conductors 20) to which multiple memory cells are coupled (as shown). Other memory array configurations may be used, as may multiple levels of memory.

For example, FIG. 2C is a simplified perspective view of a portion of a monolithic three dimensional array 40a that includes a first memory level 42 positioned below a second memory level 44. Memory levels 42 and 44 each include a plurality of memory cells 10 in a cross-point array. Persons of ordinary skill in the art will understand that additional layers (e.g., an interlevel dielectric) may be present between the first and second memory levels 42 and 44, but are not shown in FIG. 2C for simplicity. Other memory array configurations may be used, as may additional levels of memory. In the embodiment of FIG. 2C, all diodes may “point” in the same direction, such as upward or downward depending on whether p-i-n diodes having a p-doped region on the bottom or top of the diodes are employed, simplifying diode fabrication.

In some embodiments, the memory levels may be formed as described in U.S. Pat. No. 6,952,030, titled “High-Density Three-Dimensional Memory Cell” which is hereby incorporated by reference herein in its entirety for all purposes. For instance, the upper conductors of a first memory level may be used as the lower conductors of a second memory level that is positioned above the first memory level as shown in the alternative example three dimensional memory array 40b illustrated in FIG. 2D.

In such embodiments, the diodes on adjacent memory levels preferably point in opposite directions as described in U.S. patent application Ser. No. 11/692,151, filed Mar. 27, 2007, and titled “Large Array Of Upward Pointing P-I-N Diodes Having Large And Uniform Current” (hereinafter “the '151 application”), which is hereby incorporated by reference herein in its entirety for all purposes.

For example, as shown in FIG. 2D, the diodes of the first memory level 42 may be upward pointing diodes as indicated by arrow D1 (e.g., with p regions at the bottom of the diodes), whereas the diodes of the second memory level 44 may be downward pointing diodes as indicated by arrow D2 (e.g., with n regions at the bottom of the diodes), or vice versa.

A monolithic three dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in Leedy, U.S. Pat. No. 5,915,167, titled “Three Dimensional Structure Memory.” The substrates may be thinned or removed from the memory levels before bonding, but as the memory levels are initially formed over separate substrates, such memories are not true monolithic three dimensional memory arrays.

FIG. 3A is a cross-sectional view of an example embodiment of memory cell 10 of FIGS. 1 and 2. In particular, FIG. 3A shows an example memory cell 10 which includes multi-layer antifuse structure 12, diode 14, and first and second conductors 20 and 22, respectively. Memory cell 10 also may include bottom electrode 24, barrier layer 26, top electrode 28, a silicide layer 50, a silicide-forming metal layer 52, and dielectric material layer 54, as well as adhesion layers, antireflective coating layers and/or the like (not shown) which may be used with first and/or second conductors 20 and 22, respectively, to improve device performance and/or facilitate device fabrication.

Diode 14 may be a vertical p-n or p-i-n diode, which may either point upward or downward. In the embodiment of FIG. 2D in which adjacent memory levels share conductors, adjacent memory levels preferably have diodes that point in opposite directions such as downward-pointing p-i-n diodes for a first memory level and upward-pointing p-i-n diodes for an adjacent, second memory level (or vice versa).

In some embodiments, diode 14 may be formed from a polycrystalline semiconductor material such as polysilicon, a polycrystalline silicon-germanium alloy, polygermanium or any other suitable material. For example, diode 14 may include a heavily doped n+ polysilicon region 14a, a lightly doped or an intrinsic (unintentionally doped) polysilicon region 14b above the n+ polysilicon region 14a, and a heavily doped p+ polysilicon region 14c above intrinsic region 14b. It will be understood that the locations of the n+ and p+ regions may be reversed.

In some embodiments, a thin germanium and/or silicon-germanium alloy layer (not shown) may be formed on n+ polysilicon region 14a to prevent and/or reduce dopant migration from n+ polysilicon region 14a into intrinsic region 14b. Use of such a layer is described, for example, in U.S. patent application Ser. No. 11/298,331, filed Dec. 9, 2005 and titled “Deposited Semiconductor Structure To Minimize N-Type Dopant Diffusion And Method Of Making” (hereinafter “the '331 application”), which is hereby incorporated by reference herein in its entirety for all purposes. In some embodiments, a few hundred angstroms or less of silicon-germanium alloy with about 10 at % or more of germanium may be employed.

Barrier layer 26, such as titanium, TiN, tantalum, TaN, tungsten, WN, molybdenum, etc., may be formed between first conductor 20 and n+ region 14a (e.g., to prevent and/or reduce migration of metal atoms into the polysilicon regions).

If diode 14 is fabricated from deposited silicon (e.g., amorphous or polycrystalline), a silicide layer 50 may be formed on diode 14 to place the deposited silicon in a low resistivity state, as fabricated, such as described in Brad Herner et al., “Polysilicon Memory Switching: Electrothermal-Induced Order,” IEEE Trans. Electron. Devices, 53:9, pp. 2320-2327 (September 2006). Such a low resistivity state allows for easier programming of memory cell 10 as a large voltage is not required to switch the deposited silicon to a low resistivity state.

For example, a silicide-forming metal layer 52 such as titanium or cobalt may be deposited on p+ polysilicon region 14c. During a subsequent anneal step (described below), silicide-forming metal layer 52 and the deposited silicon of diode 14 interact to form silicide layer 50, consuming all or a portion of the silicide-forming metal layer 52. In some embodiments, a nitride layer (not shown) may be formed at a top surface of silicide-forming metal layer 52. For example, if silicide-forming metal layer 52 is titanium, a TiN layer may be formed at a top surface of silicide-forming metal layer 52.

A rapid thermal anneal (“RTA”) step may then be performed to form silicide regions by reaction of silicide-forming metal layer 52 with p+ region 14c. The RTA may be performed at about 600° C. to about 750° C. for about 1 minute, and causes silicide-forming metal layer 52 and the deposited silicon of diode 14 to interact to form silicide layer 50, consuming all or a portion of silicide-forming metal layer 52. An additional, higher temperature anneal (e.g., such as at about 750° C. as described below) may be used to crystallize the diode.

As described in U.S. Pat. No. 7,176,064, titled “Memory Cell Comprising A Semiconductor Junction Diode Crystallized Adjacent To A Silicide,” which is hereby incorporated by reference herein in its entirety for all purposes, silicide-forming materials such as titanium and/or cobalt react with deposited silicon during annealing to form a silicide layer. The lattice spacings of titanium silicide and cobalt silicide are close to that of silicon, and it appears that such silicide layers may serve as “crystallization templates” or “seeds” for adjacent deposited silicon as the deposited silicon crystallizes (e.g., the silicide layer enhances the crystalline structure of diode 14 during annealing). Lower resistivity silicon thereby is provided. Similar results may be achieved for silicon-germanium alloy and/or germanium diodes.

In embodiments in which a nitride layer was formed at a top surface of silicide-forming metal layer 52, following the RTA step, the nitride layer may be stripped using a wet chemistry. For example, if silicide-forming metal layer 52 includes a TiN top layer, a wet chemistry (e.g., ammonium, peroxide, water in a 1:1:1 ratio) may be used to strip any residual TiN. In some embodiments, the nitride layer formed at a top surface of silicide-forming metal layer 52 may remain, or may not be used at all.

Bottom electrode 24 is formed above silicide-forming metal layer 52. In some embodiments, bottom electrode 24 may have a thickness between about 20 angstroms and about 150 angstroms, more generally between about 10 angstroms and about 250 angstroms, although other thicknesses may be used. In some embodiments, bottom electrode 24 may be titanium, TiN, tantalum, TaN, tungsten, WN, molybdenum, carbon or another similar material. In an example embodiment in accordance with this invention, bottom electrode 24 is TiN. Bottom electrode 24 may be formed by atomic layer deposition (“ALD”), chemical vapor deposition (“CVD”), physical vapor deposition (“PVD”), plasma-enhanced CVD (“PECVD”), sputter deposition, or other similar processes.

As described in more detail below, multi-layer antifuse structure 12 is formed above bottom electrode 24. Top electrode 28 is formed above multi-layer antifuse structure 12. In some embodiments, top electrode 28 may have a thickness between about 20 angstroms and about 100 angstroms, more generally between about 10 angstroms and about 250 angstroms, although other thicknesses may be used. In some embodiments, top electrode 28 may be titanium, TiN, tantalum, TaN, tungsten, WN, or another similar material. In an example embodiment in accordance with this invention, top electrode 28 is TiN. Top electrode 28 may be formed by ALD, CVD, PVD, PECVD, sputter deposition, or other similar processes. Persons of ordinary skill in the art will understand that top electrode 28 also may function as an adhesion layer for second conductor 22. Bottom electrode 24, multi-layer antifuse structure 12 and top electrode 28 form MIM stack 30.

Referring now to FIGS. 3B-3G, various example embodiments of MIM stack 30 are described. Referring now to FIG. 3B, a first example MIM stack 30b is described that includes multi-layer antifuse structure 12 disposed between bottom electrode 24 and top electrode 28. Multi-layer antifuse structure 12 includes a first dielectric material layer 12a, a second dielectric material layer 12b formed above dielectric material layer 12a, and a third dielectric material layer 12c formed above second dielectric material layer 12b. In this regard, MIM stack 30b may be referred to as a metal-insulator-insulator-insulator-metal (“MIIIM”) stack. Persons of ordinary skill in the art will understand that multi-layer antifuse structure 12 may include more than three dielectric material layers stacked on one another.

In some embodiments, first dielectric material layer 12a may have a thickness between about 15 angstroms and about 25 angstroms, more generally between about 10 angstroms and about 30 angstroms, although other thicknesses may be used. In some embodiments, second dielectric material layer 12b may have a thickness between about 25 angstroms and about 35 angstroms, more generally between about 20 angstroms and about 40 angstroms, although other thicknesses may be used. In some embodiments, third dielectric material layer 12c may have a thickness between about 20 angstroms and about 30 angstroms, more generally between about 10 angstroms and about 30 angstroms, although other thicknesses may be used.

In some embodiments, first dielectric material layer 12a is formed using a dielectric material that has a first band gap, second dielectric material layer 12b is formed using a dielectric material that has a second band gap smaller than the first band gap, and third dielectric material layer 12c is formed using a dielectric material that has a third band gap larger than the second band gap.

For example, first dielectric material layer 12a may be silicon dioxide (“SiO₂”) (band gap of about 9 eV), second dielectric material layer 12b may be hafnium oxide (“HfO₂”) (band gap of about 6 eV), and third dielectric material layer 12c may be SiO₂ (band gap of about 9 eV). In this example, second dielectric material layer 12b has a conduction band offset to first dielectric material layer 12a and third dielectric material layer 12c, which creates a quantum well that can store charge.

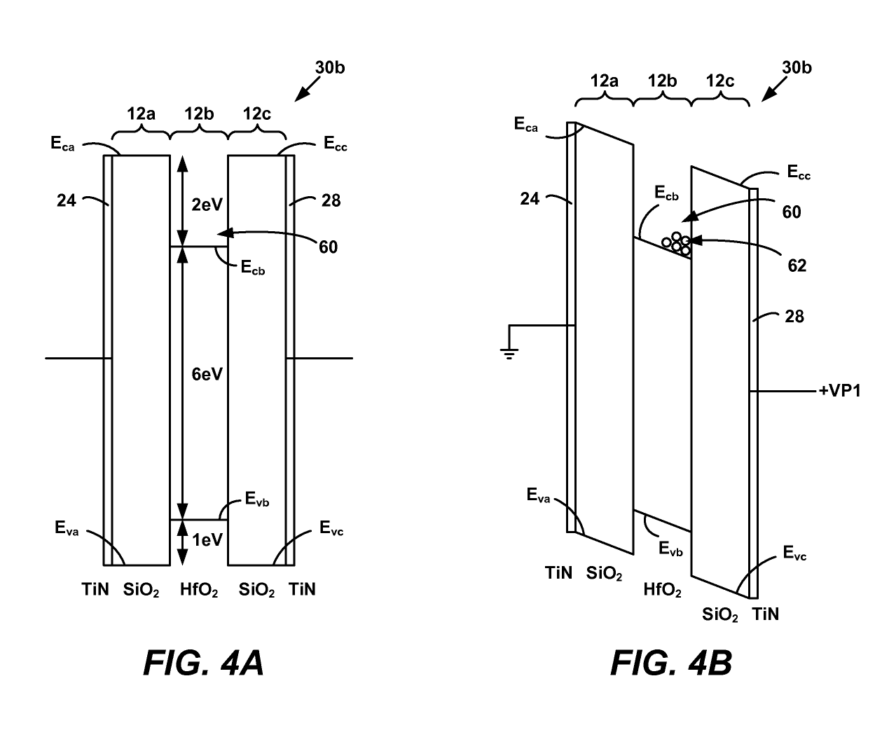

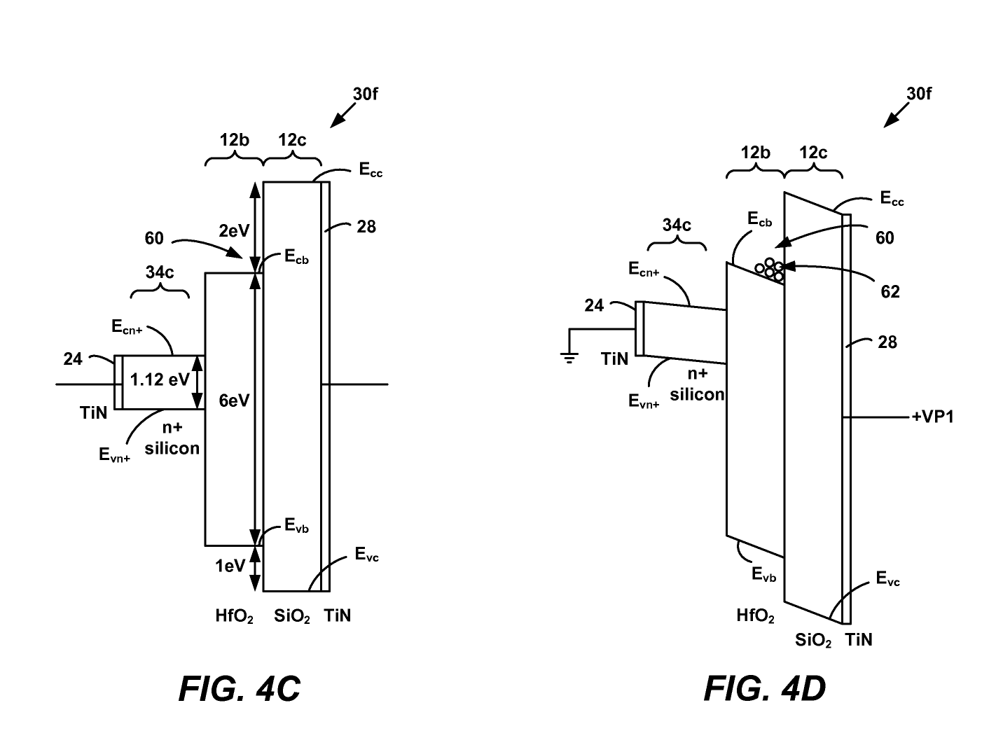

For example, FIG. 4A illustrates an example energy band diagram for MIM stack 30b under 0 volt applied bias. First dielectric material layer 12a has a valence band Eᵥₐ and a conduction band E_{ca}, second dielectric material layer 12b has a valence band E_{vb} and a conduction band E_{cb}, and third dielectric material layer 12c has a valence band E_{vc} and a conduction band E_{cc}. As the diagram illustrates, second dielectric material layer 12b has a conduction band offset of about 2 eV from the first and third dielectric material layers 12a and 12c, which creates a quantum well 60 that can store charge.

FIG. 4B illustrates an example energy band diagram for MIM stack 30b if a first programming voltage VP1 is applied across MIM stack 30b as shown. Without wanting to be bound by any particular theory, it is believed that charge carriers 62 tunnel through first dielectric material layer 12a and are blocked by third dielectric material layer 12c. The blocked charges 62 at the interface between second dielectric material layer 12b and third dielectric material layer 12c cause an increase in tunneling through memory cell 10.

As described in more detail below, this increased tunneling current corresponds to a second memory state of memory cell 10. Without wanting to be bound by any particular theory, it is believed that second memory state is more controllable and reproducible than corresponding second memory states in prior art multi-level dielectric antifuse memory cells.

Referring again to FIG. 3B, persons of ordinary skill in the art will understand that other dielectric materials may be used for first dielectric material layer 12a, second dielectric material layer 12b and third dielectric material layer 12c, and that first dielectric material layer 12a and third dielectric material layer 12c do not have to be formed from the same dielectric material.

For example, first dielectric material layer 12a may be SiO₂, Al₂O₃, Si₃N₄, or other similar dielectric material, second dielectric material layer 12b may be HfO₂, ZrO₂, La₂O₃, Ta₂O₅, TiO₂, SrTiO₃, or other similar dielectric material, and third dielectric material layer 12c may be SiO₂, Al₂O₃, Si₃N₄, or other similar dielectric material. Other similar dielectric materials may be used.

First dielectric material layer 12a, second dielectric material layer 12b and third dielectric material layer 12c may be formed over TiN bottom electrode 24 using any suitable formation process, such as ALD, PVD, rapid thermal oxidation (“RTO”), high density plasma CVD (“HDP-CVD”), CVD, or slot plan antenna plasma technology (“SPA”). Persons of ordinary skill in the art will understand that other processes may be used to form first dielectric material layer 12a, second dielectric material layer 12b and third dielectric material layer 12c.

In addition, although the example described above uses TiN for bottom electrode 24 and top electrode 28, persons of ordinary skill in the art will understand that bottom electrode 24 and/or top electrode 28 may be formed using other conductive materials. For example, titanium aluminum nitride (“TiAlN”) or WN may be used for bottom electrode 24 and/or top electrode 28 to reduce the programming voltage of memory cell 10.

Referring again to FIG. 3B, upon application of a second programming voltage VP2 across memory cell 10, multi-layer antifuse structure 12 exhibits soft breakdown, and switches to a third conductivity, corresponding to a third memory state of memory cell 10. As described above, during soft breakdown, dielectric material begins to break down, without experiencing complete dielectric breakdown. In addition, if second dielectric material layer 12b is thicker than first dielectric material layer 12a and third dielectric material layer 12c, it is believed that the thicker second dielectric material layer 12b experiences soft breakdown, while first dielectric material layer 12a and third dielectric material layer 12c begin to leak, but remain substantially intact. In this regard, it is believed that the resistance of first dielectric material layer 12a and/or third dielectric material layer 12c may limit capacitive discharge through multi-layer antifuse structure 12 during a programming event, resulting in greater control of the soft breakdown process.

In accordance with this invention, to provide additional current limiting for multi-layer antifuse structure 12, additional material layers may be coupled to first dielectric material layer 12a and/or third dielectric material layer 12c. For example, referring now to FIG. 3C, an alternative example MIM stack 30c is similar to MIM stack 30b, but also includes a first conductive layer 34a disposed between bottom electrode 24 and first dielectric material layer 12a. First conductive layer 34a may be formed using highly doped polysilicon, Ge doped polysilicon, amorphous carbon (“αC”) or other similar material.

For example, in some embodiments, first conductive layer 34a may be n+ polysilicon having a doping concentration between about 1×10²⁰ cm⁻³ and about 1×10²² cm⁻³. Persons of ordinary skill in the art will understand that other doping types and doping concentrations may be used. First conductive layer 34a may have a thickness of about 200 angstroms and about 400 angstroms, more generally between about 100 angstroms and about 1000 angstroms, although other thicknesses may be used. First conductive layer 34a may be formed by, CVD, low pressure CVD (“LPCVD”), PECVD, sputter deposition, or other similar processes.

Without wanting to be bound by any particular theory, it is believed that first conductive layer 34a may act as in-situ current limiter, and may limit capacitive discharge through MIM stack 30c during a programming event. For example, upon application of second programming voltage VP2 across memory cell 10, multi-layer antifuse 12 exhibits soft-breakdown, and switches to a third conductivity, corresponding to a third memory state of memory cell 10. The additional current limiting provided by first conductive layer 34a may provide better control for the soft-breakdown.

Referring now to FIG. 3D, another alternative example MIM stack 30d is described. MIM stack 30d is similar to MIM stack 30b, but also includes a second conductive layer 34b disposed between top electrode 28 and third dielectric material layer 12c. Second conductive layer 34b may be formed using highly doped polysilicon, Ge doped polysilicon, αC or other similar material.

For example, in some embodiments, second conductive layer 34b may be n+ silicon, such as described above in connection with first conductive layer 34a in FIG. 3C. Second conductive layer 34a may have a thickness of about 200 angstroms and about 400 angstroms, more generally between about 100 angstroms and about 1000 angstroms, although other thicknesses may be used. Second conductive layer 34b may be formed by CVD, LPCVD, PECVD, sputter deposition, or other similar processes.

Without wanting to be bound by any particular theory, it is believed that second conductive layer 34b may act as in-situ current limiter, and may limit capacitive discharge through MIM stack 30d during a programming event. For example, upon application of second programming voltage VP2 across memory cell 10, multi-layer antifuse 12 exhibits soft-breakdown, and switches to a third conductivity, corresponding to a third memory state of memory cell 10. The current limiting provided by second conductive layer 34b may provide better control for the soft-breakdown.

Referring now to FIG. 3E, still another alternative example MIM stack 30e is described. MIM stack 30e is similar to MIM stack 30b, but also includes a first conductive layer 34a disposed between bottom electrode 24 and first dielectric material layer 12a, and a second conductive layer 34b disposed between top electrode 28 and third dielectric material layer 12c. First and second conductive layers 34a and 34b each may be formed using highly doped silicon, or other similar material, and may act as in-situ current limiters, such as described above in connection with FIGS. 3C and 3D.

Referring now to FIG. 3F, yet another example MIM stack 30f is described. MIM stack 30f includes multi-layer antifuse structure 12′ between bottom electrode 24 and top electrode 28b. Multi-layer antifuse structure 12′ includes multiple layers of dielectric material stacked on one another, without a metal or other conductive layer disposed between adjacent layers of dielectric material.

In particular, multi-layer antifuse structure 12′ includes a second dielectric material layer 12b, and a third dielectric material layer 12c formed on second dielectric material layer 12b. Persons of ordinary skill in the art will understand that multi-layer antifuse structure 12′ may include more than two dielectric material layers stacked on one another.

In addition, MIM stack 30f includes a third conductive layer 34c disposed between bottom electrode 24 and second dielectric material layer 12b. Third conductive layer 34c is a conductive material that has a first work function Φ1, and second dielectric material layer 12b has a second work function Φ₂, such that the work function difference Φ1−Φ2 is sufficient to form a conduction band offset.

For example, third conductive layer 34c may be n+ silicon, or any other conductive material having a work function similar to silicon, and second dielectric material layer 12b may be HfO₂, or any other dielectric material having a work function similar to HfO₂. In some embodiments, third conductive layer 34c may be n+ silicon having a doping concentration between about 1×10²⁰ cm⁻³ and about 1×10²² cm⁻³. Persons of ordinary skill in the art will understand that other doping types and doping concentrations may be used.

Third conductive layer 34c may have a thickness of about 200 angstroms and about 400 angstroms, more generally between about 100 angstroms and about 1000 angstroms, although other thicknesses may be used. Third conductive layer 34c may be formed by CVD, LPCVD, PECVD, sputter deposition, or other similar processes.

As described above in connection with FIG. 3B, in some embodiments, second dielectric material layer 12b may have a thickness of about 25 angstroms and about 35 angstroms, more generally between about 20 angstroms and about 40 angstroms, although other thicknesses may be used. In some embodiments, third dielectric material layer 12c may have a thickness of about 20 angstroms and about 30 angstroms, more generally between about 10 angstroms and about 30 angstroms, although other thicknesses may be used.

In some embodiments, second dielectric material layer 12b is formed using a dielectric material that has a second band gap, and third dielectric material layer 12c is formed using a dielectric material that has a third band gap larger than the second band gap.

For example, second dielectric material layer 12b may HfO₂ (band gap of about 6 eV), and third dielectric material layer 12c may be SiO₂ (band gap of about 9 eV). In this example, second dielectric material layer 12b has a conduction band offset to bottom electrode 34c and third dielectric material layer 12c, which creates a quantum well that can store charge.

For example, FIG. 4C illustrates an example energy band diagram for MIM stack 30f under 0 volt applied bias. Third conductive layer 34c has a valence band Eᵥₙ₊ and a conduction band E_{cn+}, second dielectric material layer 12b has a valence band E_{vb} and a conduction band E_{cb}, and third dielectric material layer 12c has a valence band E_{vc} and a conduction band E_{cc}. As the diagram illustrates, second dielectric material layer 12b has a conduction band offset of about 2 eV from third dielectric material layers 12a and 12c, which creates a quantum well 60 that can store charge.

FIG. 4D illustrates an example energy band diagram if first programming voltage VP1 is applied across MIM stack 30f as shown. Without wanting to be bound by any particular theory, it is believed that charge carriers 62 will tunnel through and are blocked due to band offset created by the third dielectric material layer 12c. The blocked charges in the dielectric system increase the leakage through memory cell 10. As described in more detail below, this increased leakage current corresponds to a second memory state of memory cell 10.

Further, as described above in connection with FIGS. 3C-3E, it is believed that third conductive layer 34c may also act as local resistor which helps in limiting transient current spikes and limit capacitive discharge through MIM stack 30f during a programming event.

Although not shown in FIG. 3F, persons of ordinary skill in the art will understand that if third conductive layer 34c is formed from n+ silicon, and second dielectric material layer 12b is formed from HfO₂, a thin SiO₂ layer may be formed between third conductive layer 34c and HfO₂ second dielectric material layer 12b as a result of high temperature process steps in manufacturing and contact of silicon and HfO₂.

Referring now to FIG. 3G, still another example MIM stack 30g is described. In this example embodiment, MIM stack 30g includes multi-layer antifuse structure 12 disposed between n+ polysilicon region 14a and top electrode 28. That is, MIM stack 30g shares n+ polysilicon region 14a with diode 14, and functions not only as part of diode 14, but also may act as in-situ current limiter, and may limit capacitive discharge through MIM stack 30g during a programming event. In this regard, bottom electrode 24 may be eliminated. As shown in FIG. 3G, MIM stack 30g also may include second conductive layer 34b, such as described above in connection with FIGS. 3D-3E.

Referring again to FIG. 3A, second conductor 22 is formed above MIM stack 30. Second conductor 22 may include one or more barrier layers and/or adhesion layers (not shown) deposited over MIM stack 30 prior to deposition of a conductive layer used to form second conductors 22. Second conductors may be formed from any suitable conductive material such as tungsten, another suitable metal, a conductive silicide, a conductive silicide-germanide, a conductive germanide, or the like deposited by PVD or any other any suitable method (e.g., CVD, etc.). Other conductive layer materials may be used. The deposited conductive layer and optional barrier and/or adhesion layer may be patterned and etched to form second conductors 22. In at least one embodiment, second conductors 22 are substantially parallel, substantially coplanar conductors that extend in a different direction than first conductors 20.

### Programming and Sensing

As described above, memory cells 10 in accordance with this invention include a multi-layer antifuse structure 12 that may be used to provide more than two substantially stable conductivity values, which may be sensed as more than two substantially distinct data states. For example, memory cell 10 of FIGS. 3A-3G may be used to provide at least four substantially distinct data states.

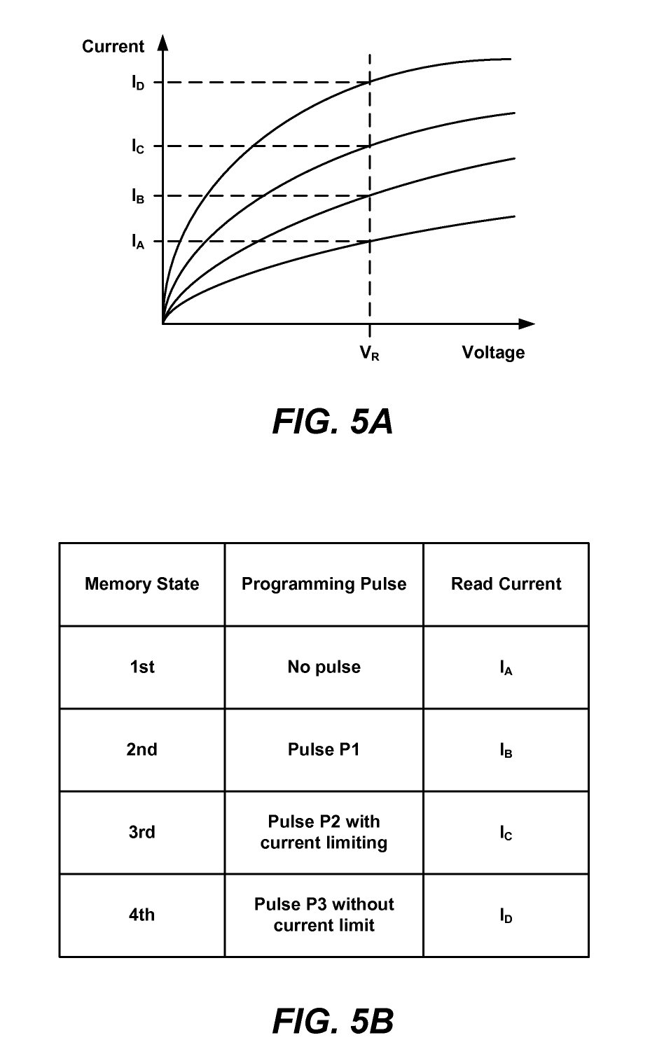

Referring to FIGS. 5A and 5B, example current and voltage characteristics of a four-state memory cell in accordance with this invention, such as memory cell 10, are described. Persons of ordinary skill in the art will understand that memory cells in accordance with this invention may have more or less than four data states.

If a read voltage V_{R} is applied across memory cell 10 as formed, a first read current I_{A} flows through the device. Read voltage V_{R} may be about 1V to about 2V, although other voltage values may be used. First read current I_{A} may be about 0.5 nA to about 5 nA, although other current values may be used. First read current I_{A} corresponds to a first data state of memory cell 10.

To program memory cell 10 to a second data state, a first programming pulse P1 having a first programming voltage VP1 is applied across memory cell 10, and additionally in some embodiments the current to the cell is limited by on-chip resistors or transistors. After the pulse, the read current is measured. This process may be iteratively repeated until a second predetermined read current I_{B} flows through memory cell 10 upon application of read voltage V_{R}. The second predetermined read current I_{B} corresponds to a second data state of memory cell 10, and may be about 20 nA to about 100 nA, although other values may be used.

First programming pulse P1 may have a first programming voltage VP1 between about 9V and about 10V, more generally between about 8V and about 13V, may have a pulse width of between about fps and about 100 μs, and may have rise and fall times between about 20 ns and about 100 ns. Other voltage values, pulse widths and/or rise and fall times may be used. The voltage value may be determined by the field needed for a charge carrier to tunnel through the first dielectric material layer 12a barrier, which will depend on the thickness, the type of dielectric combination used. Persons of ordinary skill in the art will understand that first programming pulse P1 alternatively may be a current pulse.

To program memory cell 10 to a third data state, a second programming pulse P2 having a second programming voltage VP2 is applied across memory cell 10, while limiting current through the device, and the read current is measured. This process may be iteratively repeated until a third predetermined read current I_{c} flows through memory cell 10 upon application of read voltage V_{R}. The third predetermined read current I_{c} corresponds to a third data state of memory cell 10, and may be about 0.5 μA to about 1 μA, although other values may be used.

Second programming pulse P2 may have a second programming voltage VP2 between about 8V and about 9.5V, more generally between about 4V and about 11V, may have a pulse width of between about fps and about 10 μs, and may have rise and fall times between about 20 ns and about 100 ns. Current limits between about 5 μA and about 50 μA may be used. Other voltage values, pulse widths, rise and fall times and/or current limits may be used. Persons of ordinary skill in the art will understand that second programming pulse P2 alternatively may be a current pulse.

Limiting the current while applying the programming pulse is important to avoid over-programming the memory cell. Current limiting may be achieved through external resistors, on-chip resistors, or other similar techniques. Arrays of memory cells, such as memory cells 10, typically are driven by CMOS logic transistors, which may be used to provide current limiting. In addition, using on-chip resistors, preferably closely located to the memory cells, may be more effective in terms of reducing parasitic capacitive discharge current flowing through the memory cell. For example, as described above in connection with FIGS. 3C-3G, an on-chip resistor for memory cell 10 may be provided by including n+ polysilicon layers 34a, 34b and/or 34c in MIM stack 30.

To program memory cell 10 to a fourth data state, a second programming pulse P3 having a third programming voltage VP3 is applied across memory cell 10 without limiting current through the device, and the read current is measured. This process may be iteratively repeated until a fourth predetermined read current I_{D} flows through memory cell 10 upon application of read voltage V_{R}. The fourth predetermined read current I_{D} corresponds to a fourth data state of memory cell 10, and may be about 5 μA to about 20 μA, although other values may be used.

Third programming pulse P3 may have a third programming voltage VP3 between about 10V and about 12V, more generally between about 5V and about 13V, may have a pulse width of about fps to about 10 μs, and may have rise and fall times of about 10 ns to about 50 ns. Other voltage values, pulse widths, and/or rise and fall times may be used. Persons of ordinary skill in the art will understand that third programming pulse P3 alternatively may be a current pulse.

Memory cell 10 thus can be in any one of four possible data states, as summarized in FIG. 5B. The first data state (sometimes referred to as the “virgin state”) is the state of memory cell 10 as formed, without any programming pulses having been applied to the device. The second data state is the state of memory cell 10 after first program pulse P1 has been applied to the device to achieve the target current level I_{B}, the third data state is the state of memory cell 10 after the second program pulse P2 has been applied to the device to achieve the target current level I_{c}, and the fourth data state is the state of memory cell 10 after the third program pulse P3 has been applied to the device to achieve the target current level I_{D}. Program pulses P1, P2 and P3 may be applied independently of one another (e.g., third program pulse P3 may be applied to memory cell 10 without first applying program pulses P1 and P2).

As described above, memory cell 10 may be read by applying read voltage V_{R} across memory cell 10, and sensing a read current while applying read voltage V_{R}. The sensed read current corresponds to the data state of memory cell 10. The four predetermined read current values I_{A}, I_{B}, I_{c} and I_{D} are different from one another so that each unique data state may be sensed.

Memory cells in accordance with this invention may be used as one-time programmable memory cells. In addition, some memory cells in accordance with this invention may be used as rewriteable memory cells. In particular, a soft breakdown state in some materials including HfOₓ is reversible by applying a pulse of reverse polarity (or same polarity with lower or higher voltages and/or with lower or higher pulse width with current limiting through resistor, transistor or by CMOS logic circuitry.). Thus, some memory cells in accordance with this invention may be reset from the third programming state to the second programming state by applying one or more pulses in a reverse bias direction across memory cell 10.

For example, for memory cells 10 that include a metal oxide dielectric material layer, such as embodiments in which MIM stack 30 includes an n+ bottom (or top) electrode, a SiO₂ first dielectric material layer, an HfO₂ second dielectric material layer, a SiO₂ third dielectric material layer, and a TiN top (or bottom) electrode, one or more reverse polarity pulses may be used to reset the material from a lower resistance (e.g., in memory state 3) to higher resistance (e.g., in memory state 2). Such rewritable memory cells are referred to as bipolar switching memory cells. Although HfO₂ is an example of one such dielectric material that may be used in such bipolar switching memory cells, numerous other materials may be used, such as ZrO₂, La₂O₃, Ta₂O₅, TiO₂, SrTiO₃, and other similar materials. In addition, persons of ordinary skill in the art will understand that an n+ bottom (or top) electrode may be omitted.

To reset such a bipolar switching memory cell from the third data state to the second data state, one or more reverse polarity pulses, PREV, having a voltage between about 10V and about 12V, more generally between about 5V and about 13V, are applied to memory cell 10 for about 100 ns to about 10 μs. Subsequent programming operations may be used set the memory cell to the third data state by applying one or more second programming pulses P2. In this regard, the memory cell 10 may be used as a rewriteable memory cell.

In such bipolar switching memory cells, a thin film transistor (“TFT”), such as a thin film field effect transistor, may be used as steering element 14. Without wanting to be bound by any particular theory, it is believed that a TFT steering element 14 may be used with bipolar programming pulses and may have smaller voltage drops than previously described diode steering elements 14. This may allow use of smaller magnitude reverse polarity pulses PREV compared to memory cells that use diode steering elements. Three-dimensional arrays of memory cells having multiple layers of memory cells above a substrate may use memory cells that include a memory element above or below a vertically-oriented channel TFT.

### Example Fabrication Processes for Memory Cells

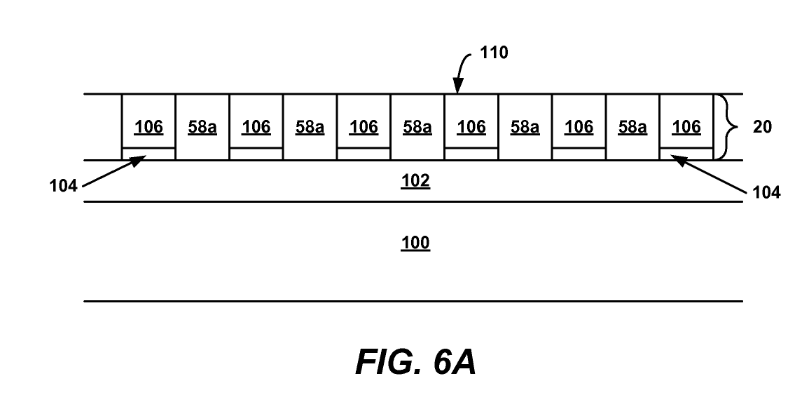

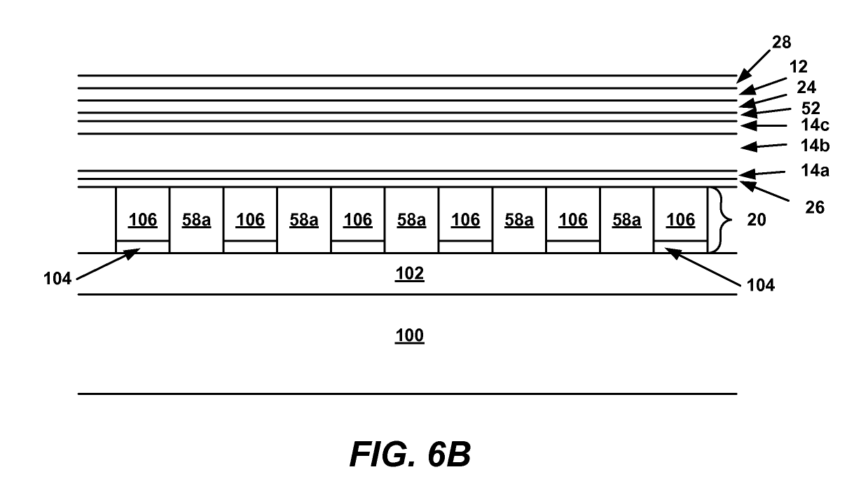

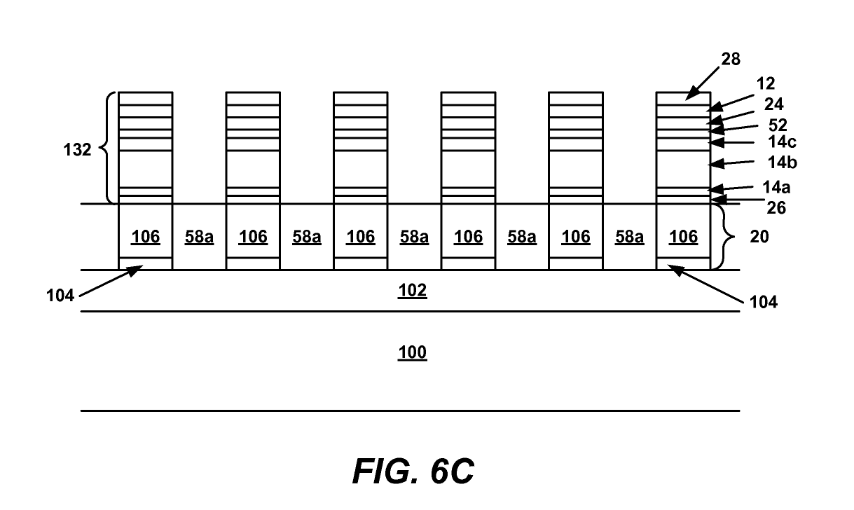

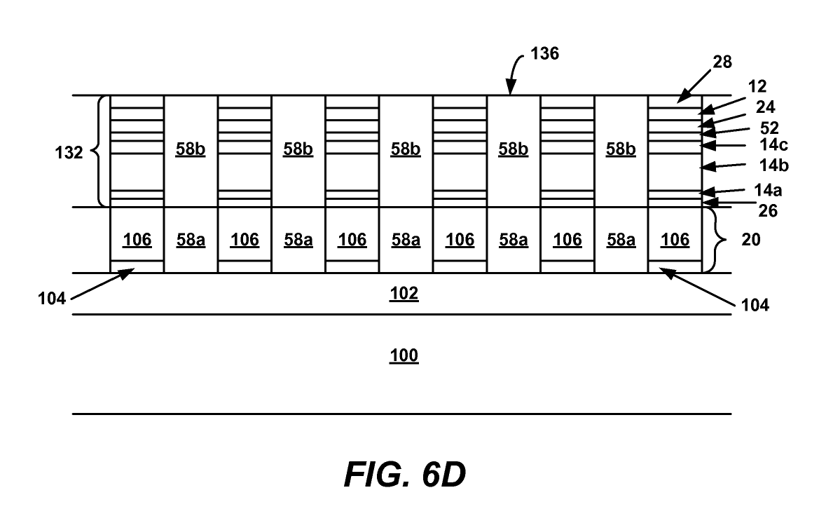

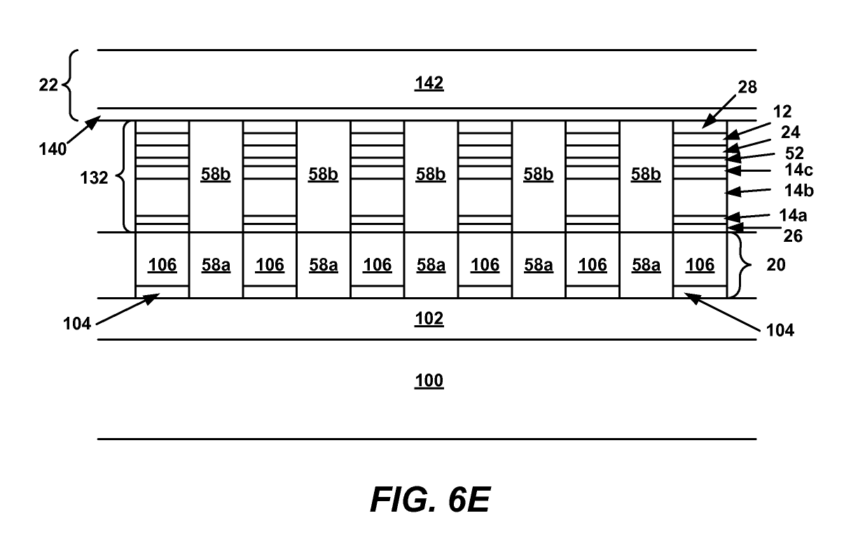

Referring now to FIGS. 6A-6E, an example method of forming a memory level in accordance with this invention is described. In particular, FIGS. 6A-6E illustrate an example method of forming a memory level including memory cells 10 of FIG. 3A. As will be described below, the first memory level includes a plurality of memory cells that each include a multi-layer antifuse structure coupled to the steering element. Additional memory levels may be fabricated above the first memory level (as described previously with reference to FIGS. 2C-2D).

With reference to FIG. 6A, substrate 100 is shown as having already undergone several processing steps. Substrate 100 may be any suitable substrate such as a silicon, germanium, silicon-germanium, undoped, doped, bulk, silicon-on-insulator (“SOI”) or other substrate with or without additional circuitry. For example, substrate 100 may include one or more n-well or p-well regions (not shown).

Isolation layer 102 is formed above substrate 100. In some embodiments, isolation layer 102 may be a layer of silicon dioxide, silicon nitride, silicon oxynitride or any other suitable insulating layer.

Following formation of isolation layer 102, an adhesion layer 104 is formed over isolation layer 102 (e.g., by PVD or another method). For example, adhesion layer 104 may be between about 20 and about 500 angstroms, and preferably about 100 angstroms, of titanium nitride or another suitable adhesion layer such as tantalum nitride, tungsten nitride, tungsten, molybdenum, combinations of one or more adhesion layers, or the like. Other adhesion layer materials and/or thicknesses may be employed. In some embodiments, adhesion layer 104 may be optional.

After formation of adhesion layer 104, a conductive layer 106 is deposited over adhesion layer 104. Conductive layer 106 may include any suitable conductive material such as tungsten or another appropriate metal, heavily doped semiconductor material, a conductive silicide, a conductive silicide-germanide, a conductive germanide, or the like deposited by any suitable method (e.g., CVD, PVD, etc.). In at least one embodiment, conductive layer 106 may comprise between about 200 and about 2500 angstroms of tungsten. Other conductive layer materials and/or thicknesses may be used.

Following formation of conductive layer 106, adhesion layer 104 and conductive layer 106 are patterned and etched. For example, adhesion layer 104 and conductive layer 106 may be patterned and etched using conventional lithography techniques, with a soft or hard mask, and wet or dry etch processing. In at least one embodiment, adhesion layer 104 and conductive layer 106 are patterned and etched to form substantially parallel, substantially co-planar first conductors 20. Example widths for first conductors 20 and/or spacings between first conductors 20 range between about 200 and about 2500 angstroms, although other conductor widths and/or spacings may be used.

After first conductors 20 have been formed, a dielectric material layer 58a is formed over substrate 100 to fill the voids between first conductors 20. For example, approximately 3000-7000 angstroms of silicon dioxide may be deposited on the substrate 100 and planarized using chemical mechanical polishing or an etchback process to form a planar surface 110. Planar surface 110 includes exposed top surfaces of first conductors 20 separated by dielectric material (as shown). Other dielectric materials such as silicon nitride, silicon oxynitride, low K dielectrics, etc., and/or other dielectric material layer thicknesses may be used. Example low K dielectrics include carbon doped oxides, silicon carbon layers, or the like.

In other embodiments of the invention, first conductors 20 may be formed using a damascene process in which dielectric material layer 58a is formed, patterned and etched to create openings or voids for first conductors 20. The openings or voids then may be filled with adhesion layer 104 and conductive layer 106 (and/or a conductive seed, conductive fill and/or barrier layer if needed). Adhesion layer 104 and conductive layer 106 then may be planarized to form planar surface 110. In such an embodiment, adhesion layer 104 will line the bottom and sidewalls of each opening or void.

Following planarization, the diode structures of each memory cell are formed. With reference to FIG. 6B, a barrier layer 26 is formed over planarized top surface 110 of substrate 100. In some embodiments, barrier layer 26 may be between about 20 and about 500 angstroms, and preferably about 100 angstroms, of titanium nitride or another suitable barrier layer such as tantalum nitride, tungsten nitride, tungsten, molybdenum, combinations of one or more barrier layers, barrier layers in combination with other layers such as titanium/titanium nitride, tantalum/tantalum nitride or tungsten/tungsten nitride stacks, or the like. Other barrier layer materials and/or thicknesses may be employed.

After deposition of barrier layer 26, deposition of the semiconductor material used to form the diode of each memory cell begins (e.g., diode 14 in FIGS. 1 and 3A). Each diode may be a vertical p-n or p-i-n diode as previously described. In some embodiments, each diode is formed from a polycrystalline semiconductor material such as polysilicon, a polycrystalline silicon-germanium alloy, polygermanium or any other suitable material. For convenience, formation of a polysilicon, downward-pointing diode is described herein. It will be understood that other materials and/or diode configurations may be used.

With reference to FIG. 6B, following formation of barrier layer 26, a heavily doped n+ silicon layer 14a is deposited on barrier layer 26. In some embodiments, n+ silicon layer 14a is in an amorphous state as deposited. In other embodiments, n+ silicon layer 14a is in a polycrystalline state as deposited. CVD or another suitable process may be employed to deposit n+ silicon layer 14a. In at least one embodiment, n+ silicon layer 14a may be formed, for example, from about 100 to about 1000 angstroms, preferably about 100 angstroms, of phosphorus or arsenic doped silicon having a doping concentration of about 10²¹ cm⁻³. Other layer thicknesses, doping types and/or doping concentrations may be used. N+ silicon layer 14a may be doped in situ, for example, by flowing a donor gas during deposition. Other doping methods may be used (e.g., implantation).

After deposition of n+ silicon layer 14a, a lightly doped, intrinsic and/or unintentionally doped silicon layer 14b may be formed over n+ silicon layer 14a. In some embodiments, intrinsic silicon layer 14b may be in an amorphous state as deposited. In other embodiments, intrinsic silicon layer 14b may be in a polycrystalline state as deposited. CVD or another suitable deposition method may be employed to deposit intrinsic silicon layer 14b. In at least one embodiment, intrinsic silicon layer 14b may be about 300 to about 4800 angstroms, preferably about 2500 angstroms, in thickness. Other intrinsic layer thicknesses may be used.

A thin (e.g., a few hundred angstroms or less) germanium and/or silicon-germanium alloy layer (not shown) may be formed on n+ silicon layer 14a prior to depositing intrinsic silicon layer 14b to prevent and/or reduce dopant migration from n+ silicon layer 14a into intrinsic silicon layer 14b (as described in the '331 application).

P-type silicon may be either deposited and doped by ion implantation or may be doped in situ during deposition to form a p+ silicon layer 14c. For example, a blanket p+ implant may be employed to implant boron a predetermined depth within intrinsic silicon layer 14b. Example implantable molecular ions include BF₂, BF₃, B and the like. In some embodiments, an implant dose of about 1−5×10¹⁵ ions/cm² may be employed. Other implant species and/or doses may be used. Further, in some embodiments, a diffusion process may be employed. In at least one embodiment, the resultant p+ silicon layer 14c has a thickness of about 100-700 angstroms, although other p+ silicon layer sizes may be used.

Following formation of p+ silicon layer 14c, a silicide-forming metal layer 52 is deposited over p+ silicon layer 14c. Example silicide-forming metals include sputter or otherwise deposited titanium or cobalt. In some embodiments, silicide-forming metal layer 52 has a thickness of about 10 to about 200 angstroms, preferably about 20 to about 50 angstroms and more preferably about 20 angstroms. Other silicide-forming metal layer materials and/or thicknesses may be used. A nitride layer (not shown) may be formed at the top of silicide-forming metal layer 52.

Following formation of silicide-forming metal layer 52, an RTA step may be performed at about 600° C. for about one minute to form silicide layer 50 (FIG. 3), consuming all or a portion of the silicide-forming metal layer 52. Following the RTA step, any residual nitride layer from silicide-forming metal layer 52 may be stripped using a wet chemistry, as described above. Other annealing conditions may be used.

Following the RTA step and the nitride strip step, bottom electrode 24 is formed above silicide layer 50. Bottom electrode 24 may be between about 20 angstroms and about 150 angstroms, more generally between about 10 angstroms and about 250 angstroms of titanium nitride or another suitable barrier layer such as tantalum nitride, tungsten nitride, tungsten, molybdenum, combinations of one or more barrier layers, barrier layers in combination with other layers such as titanium/titanium nitride, tantalum/tantalum nitride or tungsten/tungsten nitride stacks, or the like. Other barrier layer materials and/or thicknesses may be employed.

As described above, bottom electrode 24 may be formed by CVD, PVD, sputter deposition, or other similar processes. In at least one embodiment, bottom electrode 24 may be deposited without a pre-clean or pre-sputter step prior to deposition. Example deposition process conditions are as set forth in Table 1.

TABLE 1
EXAMPLE ADHESION/BARRIER LAYER
DEPOSITION PARAMETERS

| | EXAMPLE | PREFERRED |
|---|---|---|
| PROCESS PARAMETER | RANGE | RANGE |
| Argon Flow Rate (sccm) | 20-40 | 20-30 |
| Ar With Dilute H₂ (<10%) | 0-30 | 0-10 |
| Flow Rate (sccm) | | |
| Nitrogen Flow Rate (sccm) | 50-90 | 60-70 |
| Pressure (milliTorr) | 1-5000 | 1800-2400 |
| Power (Watts) | 10-9000 | 2000-9000 |
| Power Ramp Rate (Watts/sec) | 10-5000 | 2000-4000 |
| Process Temperature (° C.) | 100-600 | 200-350 |
| Deposition Time (sec) | 5-200 | 10-150 |

Other flow rates, pressures, powers, power ramp rates, process temperatures and/or deposition times may be used.

Example deposition chambers include the Endura 2 tool available from Applied Materials, Inc. of Santa Clara, Calif. Other processing tools may be used. In some embodiments, a buffer chamber pressure of about 1−2×10⁻⁷ Torr and a transfer chamber pressure of about 2−5×10⁻⁸ Torr may be used. The deposition chamber may be stabilized for about 250-350 seconds with about 60-80 sccm Ar, 60-70 sccm N₂, and about 5-10 sccm of Ar with dilute H2 at about 1800-2400 milliTorr. In some embodiments, it may take about 2-5 seconds to strike the target. Other buffer chamber pressures, transfer chamber pressures and/or deposition chamber stabilization parameters may be used.

Multi-layer antifuse structure 12 is formed above TiN bottom electrode 24. Multi-layer antifuse structure 12 includes multiple layers of dielectric material stacked on one another, without a metal or other conductive layer disposed between adjacent layers of dielectric material. As described above in connection with FIG. 3B, in an example embodiment, multi-layer antifuse structure 12 includes a first dielectric material layer 12a, a second dielectric material layer 12b formed on first dielectric material layer 12a, and a third dielectric material layer 12c formed on second dielectric material layer 12b. Persons of ordinary skill in the art will understand that multi-layer antifuse structure 12 may include more than three dielectric material layers.

In an example embodiment, first dielectric material layer 12a may have a thickness between about 15 angstroms and about 25 angstroms, more generally between about 10 angstroms and about 30 angstroms, second dielectric material layer 12b may have a thickness between about 25 angstroms and about 35 angstroms, more generally between about 20 angstroms and about 40 angstroms, and third dielectric material layer 12c may have a thickness between about 20 angstroms and about 30 angstroms, more generally between about 10 angstroms and about 30 angstroms. Other thicknesses may be used.

In an example embodiment, first dielectric material layer 12a is SiO₂, second dielectric material layer 12b is HfO₂, and third dielectric material layer 12c is SiO₂. Persons of ordinary skill in the art will understand that other dielectric materials may be used for first dielectric material layer 12a, second dielectric material layer 12b and third dielectric material layer 12c, and that first dielectric material layer 12a and third dielectric material layer 12c may be formed from different dielectric materials.

For example, first dielectric material layer 12a may be SiO₂, Al₂O₃, Si₃N₄, or other similar dielectric material, second dielectric material layer 12b may be HfO₂, ZrO₂, La₂O₃, Ta₂O₅, TiO₂, SrTiO₃, or other similar dielectric material, and third dielectric material layer 12c may be SiO₂, Al₂O₃, Si₃N₄, or other similar dielectric material. Other similar dielectric materials may be used.

First dielectric material layer 12a, second dielectric material layer 12b and third dielectric material layer 12c may be formed over TiN bottom electrode 24 using any suitable formation process, such as ALD, PVD, RTO, HDP-CVD, SPA, or other similar process. Persons of ordinary skill in the art will understand that other processes may be used to form first dielectric material layer 12a, second dielectric material layer 12b and third dielectric material layer 12c.

Persons of ordinary skill in the art will understand that first dielectric material layer 12a, second dielectric material layer 12b and third dielectric material layer 12c may all be the same thickness, or may have different thickness from one another. In addition, nitrogen may be incorporated at the interface between second dielectric material layer 12b and third dielectric material layer 12c to enhance interface state density. Further, different process flows and recipes (such as film growth conditions, stoichiometry, gas flow, etc.) can be used to control the type and quality of the film and their respective interfaces to achieve reproducible memory states.

Top electrode 28 is formed above multi-layer antifuse structure 12. Top electrode 28 may be about 20 angstroms to about 100 angstroms, more generally between about 10 angstroms and about 250 angstroms, of titanium nitride or another suitable barrier layer such as tantalum nitride, tungsten nitride, tungsten, molybdenum, combinations of one or more barrier layers, barrier layers in combination with other layers such as titanium/titanium nitride, tantalum/tantalum nitride or tungsten/tungsten nitride stacks, or the like. Other barrier layer materials and/or thicknesses may be employed.

In at least one embodiment, top electrode 28 may be deposited without a pre-clean or pre-sputter step prior to deposition. Top electrode 28 may be formed by ALD, CVD, PVD, sputter deposition, or other similar processes. Example deposition process conditions are as set forth above in Table 1.

As shown in FIG. 6C, top electrode 28, multi-layer antifuse structure 12, bottom electrode 24, silicide-forming metal layer 52, diode layers 14a-14c, and barrier layer 26 are patterned and etched to form pillars 132. Pillars 132 may be formed above corresponding conductors 20 and have substantially the same width as conductors 20, for example, although other widths may be used. Some misalignment may be tolerated. The memory cell layers may be patterned and etched in a single pattern/etch procedure or using separate pattern/etch steps. In at least one embodiment, top electrode 28, multi-layer antifuse structure 12 and bottom electrode 24 are etched together to form MIM stack 30 (FIG. 3A).

For example, photoresist may be deposited, patterned using standard photolithography techniques, layers 26, 14a-14c, 52, 24, 12, and 28 may be etched, and then the photoresist may be removed. Alternatively, a hard mask of some other material, for example silicon dioxide, may be formed on top of top electrode 28, with bottom antireflective coating (“BARC”) on top, then patterned and etched. Similarly, dielectric antireflective coating (“DARC”) may be used as a hard mask. In some embodiments, one or more additional metal layers may be formed above multi-layer antifuse structure 12 and diode 14 and used as a metal hard mask that remains part of pillars 132.

Pillars 132 may be formed using any suitable masking and etching process. For example, layers 26, 14a-14c, 52, 24, 12, and 28 may be patterned with about 1 to about 1.5 micron, more preferably about 1.2 to about 1.4 micron, of photoresist (“PR”) using standard photolithographic techniques. Thinner PR layers may be used with smaller critical dimensions and technology nodes. In some embodiments, an oxide hard mask may be used below the PR layer to improve pattern transfer and protect underlying layers during etching.

In some embodiments, after etching, pillars 132 may be cleaned using a dilute hydrofluoric/sulfuric acid clean. Such cleaning may be performed in any suitable cleaning tool, such as a Raider tool, available from Semitool of Kalispell, Mont. Example post-etch cleaning may include using ultra-dilute sulfuric acid (e.g., about 1.5-1.8 wt %) for about 60 seconds and/or ultra-dilute hydrofluoric (“HF”) acid (e.g., about 0.4-0.6 wt %) for 60 seconds. Megasonics may or may not be used. Other clean chemistries, times and/or techniques may be employed.

A dielectric material layer 58b is deposited over pillars 132 to fill the voids between pillars 132. For example, approximately 2000-7000 angstroms of silicon dioxide may be deposited and planarized using chemical mechanical polishing or an etchback process to form a planar surface 136, resulting in the structure illustrated in FIG. 6D. Planar surface 136 includes exposed top surfaces of pillars 132 separated by dielectric material 58b (as shown). Other dielectric materials such as silicon nitride, silicon oxynitride, low K dielectrics, etc., and/or other dielectric material layer thicknesses may be used.

With reference to FIG. 6E, second conductors 22 may be formed above pillars 132 in a manner similar to the formation of first conductors 20. For example, in some embodiments, one or more barrier layers and/or adhesion layers 140 may be deposited over pillars 132 prior to deposition of a conductive layer 142 used to form second conductors 22.

Barrier layer and/or adhesion layer 140 may include titanium nitride or another suitable layer such as tantalum nitride, tungsten nitride, tungsten, molybdenum, combinations of one or more layers, or any other suitable material(s). Conductive layer 142 may be formed from any suitable conductive material such as tungsten, another suitable metal, heavily doped semiconductor material, a conductive silicide, a conductive silicide-germanide, a conductive germanide, or the like deposited by PVD or any other any suitable method (e.g., CVD, etc.). Other conductive layer materials may be used.

Conductive layer 142 and barrier and/or adhesion layer 140 may be patterned and etched to form second conductors 22. In at least one embodiment, second conductors 22 are substantially parallel, substantially coplanar conductors that extend in a different direction than first conductors 20.

In other embodiments of the invention, second conductors 22 may be formed using a damascene process in which a dielectric material layer is formed, patterned and etched to create openings or voids for conductors 22. The openings or voids may be filled with adhesion layer 140 and conductive layer 142 (and/or a conductive seed, conductive fill and/or barrier layer if needed). Adhesion layer 140 and conductive layer 142 then may be planarized to form a planar surface.

Following formation of second conductors 22, the resultant structure may be annealed to crystallize the deposited semiconductor material of diodes 14 (and/or to form silicide regions by reaction of the silicide-forming metal layer 52 with p+ region 14c). In alternative embodiments, the arrangements of the doped silicon layers is reversed, so silicide-forming metal layer 52 is in contact with n+ region 14a. The lattice spacing of titanium silicide and cobalt silicide are close to that of silicon, and it appears that such silicide layers may serve as “crystallization templates” or “seeds” for adjacent deposited silicon as the deposited silicon crystallizes. Lower resistivity diode material thereby is provided. Similar results may be achieved for silicon-germanium alloy and/or germanium diodes.

Thus in at least one embodiment, a crystallization anneal may be performed for about 10 seconds to about 2 minutes in nitrogen at a temperature of about 600 to 800° C., and more preferably between about 650 and 750° C. Other annealing times, temperatures and/or environments may be used.

Additional memory levels may be similarly formed above the memory level of FIGS. 6A-6E. Persons of ordinary skill in the art will understand that alternative memory cells in accordance with this invention may be fabricated with other suitable techniques.

The foregoing description discloses only example embodiments of the invention. Modifications of the above disclosed apparatus and methods which fall within the scope of the invention will be readily apparent to those of ordinary skill in the art. For instance, in any of the above embodiments, the multi-layer antifuse structure 12 may be located below diode(s) 14.

Accordingly, although the present invention has been disclosed in connection with example embodiments thereof, it should be understood that other embodiments may fall within the spirit and scope of the invention, as defined by the following claims.

1. A memory cell comprising:
a steering element; and
a metal-insulator-metal (“MIM”) stack coupled in series with the steering element, wherein the MIM stack comprises a first dielectric material layer and a second dielectric material layer disposed on the first dielectric material layer, without a metal or other conductive layer disposed between the first dielectric material layer and the second dielectric material layer.

2. The memory cell of claim 1, wherein the steering element comprises a diode.

3. The memory cell of claim 1, wherein the steering element comprises a vertically oriented diode.

4. The memory cell of claim 1, wherein the steering element comprises a p-n or p-i-n diode.

5. The memory cell of claim 1, wherein the steering element comprises a thin film transistor.

6. The memory cell of claim 1, wherein the MIM stack is disposed above or below the steering element.

7. The memory cell of claim 1, wherein the MIM stack further comprises a third dielectric material layer disposed on the second dielectric material layer, without a metal or other conductive layer disposed between the second dielectric material layer and the third dielectric material layer.

8. The memory cell of claim 7, wherein the first dielectric material layer has a first band gap, the second dielectric material layer has a second band gap smaller than the first band gap, and the third dielectric material layer 12c is formed using a dielectric material that has a third band gap larger than the second band gap.

9. The memory cell of claim 7, wherein the first dielectric material layer comprises one or more of SiO₂, Al₂O₃, or Si₃N₄.

10. The memory cell of claim 7, wherein the second dielectric material layer comprises one or more or of HfO₂, ZrO₂, La₂O₃, Ta₂O₅, TiO₂, and SrTiO₃.

11. The memory cell of claim 7, wherein the third dielectric material layer comprises one or more of SiO₂, Al₂O₃, or Si₃N₄.

12. The memory cell of claim 7, wherein the first dielectric material layer has a thickness between about 10 angstroms and about 30 angstroms.

13. The memory cell of claim 7, wherein the second dielectric material layer has a thickness between about 20 angstroms and about 40 angstroms.

14. The memory cell of claim 7, wherein the third dielectric material layer has a thickness between about 10 angstroms and about 30 angstroms.

15. The memory cell of claim 7, wherein the MIM stack further comprises a bottom electrode disposed below the first dielectric material layer, and a top electrode disposed above the third dielectric material layer.

16. The memory cell of claim 15, wherein the MIM stack further comprises a first conductive layer disposed between the bottom electrode and the first dielectric material layer.

17. The memory cell of claim 16, wherein the first conductive layer comprises highly doped polysilicon.

18. The memory cell of claim 15, wherein the MIM stack further comprises a second conductive layer disposed between the top electrode and the third dielectric material layer.

19. The memory cell of claim 18, wherein the third conductive layer comprises highly doped polysilicon.

20. A method of programming a memory cell that includes a metal-insulator-metal (“MIM”) stack comprising a first dielectric material layer, a second dielectric material layer disposed on the first dielectric material layer, and a third dielectric material layer disposed on the second dielectric material layer, without a metal or other conductive layer disposed between the dielectric material layers, wherein the memory cell has a first memory state upon fabrication corresponding to a first read current, wherein the method comprises:
applying a first programming pulse to the memory cell, wherein the first programming pulse does not result in breakdown of the dielectric material layers, and programs the memory cell to a second memory state that corresponds to a second read current greater than the first read current.

21. The method of claim 20, further comprising applying a second programming pulse to the memory cell, wherein the second programming pulse results in soft breakdown of one or more of the dielectric material layers, and programs the memory cell to a third memory state that corresponds to a third read current greater than the second read current.

22. The method of claim 20, further comprising applying a third programming pulse to the memory cell, wherein the third programming pulse results in substantially complete breakdown of the dielectric material layers, and programs the memory cell to a fourth memory state that corresponds to a fourth read current greater than the third read current.

23. A monolithic three-dimensional memory array comprising:
a first memory level monolithically formed above a substrate, the first memory level comprising a plurality of memory cells, wherein each memory cell comprises:
a steering element; and
a metal-insulator-metal (“MIM”) stack coupled in series with the steering element, wherein the MIM stack comprises a first dielectric material layer and a second dielectric material layer disposed on the first dielectric material layer, without a metal or other conductive layer disposed between the first dielectric material layer and the second dielectric material layer; and
a second memory level monolithically formed above the first memory level.

24. The monolithic three-dimensional memory array of claim 23, wherein each steering element comprises a diode.

25. The monolithic three-dimensional memory array of claim 23, wherein each steering element comprises a vertically oriented diode.

26. The monolithic three-dimensional memory array of claim 23, wherein each steering element comprises a p-n or p-i-n diode.

27. The monolithic three-dimensional memory array of claim 23, wherein each steering element comprises a thin film transistor.

28. The monolithic three-dimensional memory array of claim 23, wherein the MIM stacks are disposed above or below the steering element.

29. The monolithic three-dimensional memory array of claim 23, wherein each MIM stack further comprises a third dielectric material layer disposed on the second dielectric material layer, without a metal or other conductive layer disposed between the second dielectric material layer and the third dielectric material layer.

30. The monolithic three-dimensional memory array of claim 29, wherein the first dielectric material layer has a first band gap, the second dielectric material layer has a second band gap smaller than the first band gap, and the third dielectric material layer 12c is formed using a dielectric material that has a third band gap larger than the second band gap.

31. The monolithic three-dimensional memory array of claim 29, wherein the first dielectric material layer comprises one or more of SiO₂, Al₂O₃, or Si₃N₄.

32. The monolithic three-dimensional memory array of claim 29, wherein the second dielectric material layer comprises one or more or of HfO₂, ZrO₂, La₂O₃, Ta₂O₅, TiO₂, and SrTiO₃.

33. The monolithic three-dimensional memory array of claim 29, wherein the third dielectric material layer comprises one or more of SiO₂, Al₂O₃, or Si₃N₄.

34. The monolithic three-dimensional memory array of claim 29, wherein the first dielectric material layer has a thickness between about 10 angstroms and about 30 angstroms.

35. The monolithic three-dimensional memory array of claim 29, wherein the second dielectric material layer has a thickness between about 20 angstroms and about 40 angstroms.

36. The monolithic three-dimensional memory array of claim 29, wherein the third dielectric material layer has a thickness between about 10 angstroms and about 30 angstroms.

37. The monolithic three-dimensional memory array of claim 29, wherein each MIM stack further comprises a bottom electrode disposed below the first dielectric material layer, and a top electrode disposed above the third dielectric material layer.

38. The monolithic three-dimensional memory array of claim 37, wherein each MIM stack further comprises a first conductive layer disposed between the bottom electrode and the first dielectric material layer.

39. The monolithic three-dimensional memory array of claim 38, wherein the first conductive layer comprises highly doped polysilicon.

40. The monolithic three-dimensional memory array of claim 37, wherein the MIM stack further comprises a second conductive layer disposed between the top electrode and the third dielectric material layer.

41. The monolithic three-dimensional memory array of claim 40, wherein the third conductive layer comprises highly doped polysilicon.
